(19) United States
(12) Patent Application Publication
(10) Pub. No.: US 2023/0170923 A1
(43) Pub. Date: Jun. 1, 2023

(54) COMMUNICATIONS MODULE

(71) Applicant: LG INNOTEK CO., LTD., Seoul (KR)

(72) Inventors: Sang Hoon SHIN, Seoul (KR); You Jin CHOI, Seoul (KR)

(21) Appl. No.: 18/011,887

(22) PCT Filed: Jun. 15, 2021
(86) PCT No.: PCT/KR2021/007455

§ 371 Date: Dec. 21, 2022

(30) Foreign Application Priority Data
Jun. 22, 2020 (KR) 10-2020-0075743
Sep. 9, 2020 (KR) 10-2020-0115117

(51) Int. Cl. H04B 1/036; H05K 1/11; H05K 7/20

(52) U.S. Cl. CPC H04B 1/036; H05K 1/111; H05K 7/20509

(57) ABSTRACT

Disclosed according to an embodiment is a communications module comprising: a first substrate having a first hole formed herein; a communications unit including a second substrate and a plurality of elements disposed on one side of the second substrate; and a heat sink disposed on the other side of the second substrate, wherein a peripheral region of the second substrate is disposed so as to vertically overlap with the periphery of the first hole of the first substrate. Accordingly, the communications module can realize an optimized heat dissipation structure in which the communications unit and the heat sink are in contact with each other on the substrate by using a thermally conductive member as a medium.

### TECHNICAL FIELD

An embodiment relates to a communication module.

### BACKGROUND ART

A communication module can be used in an electronic device such as a mobile phone or a digital camera which is miniaturized and lightened, a vehicle, or the like.

FIG. 1 is a view illustrating a conventional communication module.

Referring to FIG. 1, a conventional communication module 2 can include a substrate 10, and a communication unit 20 and a heat sink 30 disposed with the substrate 10 therebetween. Further, a thermally conductive member 40 can be disposed between the substrate 10 and the heat sink 30. Here, the thermally conductive member 40 can be a member which transfers heat by conduction, such as thermal grease.

In an arrangement structure of this communication module 2, since the communication unit 20 and the heat sink 30 are disposed with the substrate 10 therebetween, the heat generated in the communication unit 20 can be transferred to the heat sink 30 through the substrate 10 and then dissipated.

However, in the arrangement structure, there is a problem in that heat dissipation performance is deteriorated due to thermal resistance of the substrate 10.

Accordingly, there is a need for a communication module capable of implementing an optimized heat dissipation structure through the arrangement of a substrate, a communication unit, and a heat sink.

### DISCLOSURE

### Technical Problem

An embodiment is directed to providing a communication module which implements an optimized heat dissipation structure by disposing a communication unit and a heat sink on a substrate.

An embodiment is directed to providing a communication module which is compactly formed using holes formed in a substrate to minimize a thickness in a vertical direction.

An embodiment is directed to providing a communication module using connectors.

Objectives to be solved by the present invention are not limited to the above-described objectives, and other objectives, which are not described above, will be clearly understood by those skilled in the art from the following description.

### Technical Solution

One aspect of the present invention provides a communication module including: a first substrate having a first hole formed herein; a communication unit including a second substrate, and a plurality of elements disposed on one surface of the second substrate; and a heat sink disposed on the other surface of the second substrate, wherein an edge region of the second substrate is disposed to vertically overlap a periphery of the first hole of the first substrate.

Another aspect of the present invention provides a communication module including: a first substrate having a first hole formed herein; a communication unit including a second substrate on which a plurality of elements are disposed on one surface thereof; a heat sink disposed on the other surface of the second substrate; and a connector disposed between the first substrate and the second substrate.

Here, an edge region of the second substrate may be disposed to vertically overlap a periphery of the first hole of the first substrate.

Meanwhile, the communication unit may further include a plurality of pads disposed on the second substrate, and the pads may be disposed on the same surface as the surface of the second substrate, on which the elements are disposed, to be spaced apart from each other along the edge region.

Further, the communication module may further include a thermally conductive member disposed between the heat sink and the second substrate. Here, the heat sink may include a body and a plurality of heat dissipation fins formed to protrude from one surface of the body, the body may include a first protrusion protruding to further extend in a horizontal direction from a horizontal width (W4) of the plurality of heat dissipation fins, and the first substrate and the first protrusion may be coupled by fastening members.

Further, the communication unit may further include a plurality of pads disposed on the second substrate, and the pads may be disposed on a surface different from the surface of the second substrate, on which the elements are disposed, to be spaced apart from each other along the edge region.

Here, the communication module may further include a thermally conductive member disposed between the heat sink and the second substrate, and the thermally conductive member may be disposed in the first hole.

Further, the thermally conductive member may be disposed to be spaced apart from an inner surface of the first substrate forming the first hole by a predetermined distance.

In addition, the heat sink may include a body, a plurality of heat dissipation fins formed to protrude from one surface of the body, and a second protrusion formed to protrude from the other surface of the body, and the thermally conductive member may be disposed between the second protrusion and the second substrate.

In addition, the thermally conductive member and the second protrusion may be disposed to be spaced apart from an inner surface of the first substrate forming the first hole by a predetermined distance.

In addition, the body may include a first protrusion protruding to further extend in a horizontal direction from a horizontal width (W4) of the plurality of heat dissipation fins, and the first substrate and the first protrusion may be coupled by fastening members.

In addition, the communication module may further include spacers disposed so that the first substrate and the first protrusion are spaced apart from each other by a predetermined distance.

Meanwhile, the connector may include a third substrate having second holes formed therein, metal layers disposed on inner surfaces of the second holes, first metal pads disposed at one ends of the metal layers, and second metal pads disposed at the other ends of the metal layers.

Alternatively, the connector may include a third substrate having grooves formed therein, metal layers disposed on inner surfaces of the grooves, first metal pads disposed at one ends of the metal layers, and second metal pads disposed at the other ends of the metal layers, and the grooves may be concavely formed in a side surface of the third substrate in a horizontal direction.

Further, the metal layer, the first metal pad, and the second metal pad may be integrally formed.

In addition, the first metal pads may come into contact with terminals of the first substrate, and the second metal pads may come into contact with terminals of the second substrate.

In addition, the first metal pads may come into contact with terminals of the second substrate, and the second metal pads may come into contact with terminals of the first substrate.

Meanwhile, the communication module may further include a cover disposed to cover the elements, and the cover may be disposed in the first hole.

Here, the cover may include a plate part and a sidewall protruding from the plate part, and the sidewall may be disposed to be spaced apart from an inner surface of the first substrate forming the first hole by a predetermined distance.

Further, the cover may further include a blocking sidewall protruding from the plate part, and the blocking sidewall may be disposed between the elements.

Meanwhile, the elements may be elements related to a network access device (NAD).

Further, some regions of the elements may be disposed in the first hole.

In addition, the heat sink may include a body, and a pipe disposed in the body, and a cooling medium may flow through the pipe.

### Advantageous Effects

A communication module according to an embodiment can implement an optimized heat dissipation structure through a communication unit and a heat sink that come into contact with a substrate through a thermally conductive member. Here, the communication module can implement an optimized heat dissipation structure for the communication unit using a heat sink implemented in an air cooling-type, a water cooling-type, or a water and air cooling-type.

Further, a compact communication module can be implemented by minimizing a thickness in a vertical direction through a hole formed in the substrate. Accordingly, the design freedom of an apparatus and device in which the communication module is installed can be improved by minimizing interference with other components disposed at the periphery of the communication module.

Further, the communication module can have a simple structure and reduce manufacturing costs using the substrate, and can correspond to various sizes with an easy manufacturing method using connectors.

Various useful advantages and effects of the embodiments are not limited to the above-described contents and will be more easily understood from descriptions of the specific embodiments.

### DESCRIPTION OF DRAWINGS

FIG. 1 is a view illustrating a conventional communication module.

FIG. 2 is an exploded perspective view illustrating a communication module according to a first embodiment.

FIG. 3 is a view illustrating the arrangement relationship of the communication module according to the first embodiment.

FIG. 4 is a bottom perspective view illustrating a communication unit disposed in the communication module according to the first embodiment.

FIG. 5 is a view illustrating a modified example of a cover disposed in the communication module according to the first embodiment.

FIG. 6 is a view illustrating a coupling relationship by fastening members of the communication module according to the first embodiment.

FIG. 7 is an exploded perspective view illustrating a communication module according to a second embodiment.

FIG. 8 is a view illustrating the arrangement relationship of the communication module according to the second embodiment.

FIG. 9 is a bottom perspective view illustrating a first substrate disposed in the communication module according to the second embodiment.

FIG. 10 is a perspective view illustrating a communication unit disposed in the communication module according to the second embodiment.

FIG. 11 is a bottom perspective view illustrating the communication unit disposed in the communication module according to the second embodiment.

FIG. 12 is a view illustrating a coupling relationship by fastening members of the communication module according to the second embodiment.

FIG. 13 is a view illustrating spacers of the communication module according to the second embodiment.

FIG. 14 is an exploded perspective view illustrating a communication module according to a third embodiment.

FIG. 15 is a view illustrating the arrangement relationship of the communication module according to the third embodiment.

FIG. 16 is a bottom perspective view illustrating a communication unit disposed in the communication module according to the third embodiment.

FIG. 17 is a view illustrating a connector according to a first embodiment disposed in the communication module according to the third embodiment.

FIG. 18 is a view illustrating a modified example of the connector according to the first embodiment disposed in the communication module according to the third embodiment.

FIGS. 19 and 20 are views illustrating shapes of a metal layer and a metal pad of the connector according to the first embodiment disposed in the communication module according to the third embodiment.

FIG. 21 is a view illustrating a connector according to a second embodiment disposed in the communication module according to the third embodiment.

FIG. 22 is a view illustrating a modified example of the connector according to the second embodiment disposed in the communication module according to the third embodiment.

FIGS. 23 and 24 are views illustrating shapes of a metal layer and a metal pad of the connector according to the second embodiment disposed in the communication module according to the third embodiment.

FIG. 25 is a view illustrating shapes of a metal layer and a metal pad of a connector according to a third embodiment disposed in the communication module according to the third embodiment.

FIG. 26 is a view illustrating a coupling relationship by fastening members of the communication module according to the third embodiment.

FIG. 27 is an exploded perspective view illustrating a communication module according to a fourth embodiment.

FIG. 28 is a view illustrating the arrangement relationship of the communication module according to the fourth embodiment.

FIG. 29 is a perspective view illustrating a communication unit disposed in the communication module according to the fourth embodiment.

FIG. 30 is a bottom perspective view illustrating the communication unit disposed in the communication module according to the fourth embodiment.

FIG. 31 is a view illustrating a coupling relationship by fastening members of the communication module according to the fourth embodiment.

FIG. 32 is a view illustrating spacers of the communication module according to the fourth embodiment.

FIG. 33 is a perspective view illustrating a heat sink using a cooling medium according to an embodiment.

FIG. 34 is an exploded perspective view illustrating the heat sink using the cooling medium according to the embodiment.

FIG. 35 is a view illustrating the arrangement relationship of a third heat sink applied to the communication module according to the first embodiment.

FIG. 36 is a view illustrating a coupling relationship by the third heat sink and the fastening members applied to the communication module according to the first embodiment.

FIG. 37 is a view illustrating the arrangement relationship of a third heat sink applied to the communication module according to the second embodiment.

FIG. 38 is a view illustrating a coupling relationship by the third heat sink and the fastening members applied to the communication module according to the second embodiment.

FIG. 39 is a view illustrating the arrangement relationship of the third heat sink and the spacers applied to the communication module according to the second embodiment.

FIG. 40 is a view illustrating the arrangement relationship of a third heat sink applied to the communication module according to the third embodiment.

FIG. 41 is a view illustrating a coupling relationship by the third heat sink and the fastening members applied to the communication module according to the third embodiment.

FIG. 42 is a view illustrating the arrangement relationship of a third heat sink applied to the communication module according to the fourth embodiment.

FIG. 43 is a view illustrating a coupling relationship by the third heat sink and the fastening members applied to the communication module according to the fourth embodiment.

FIG. 44 is a view illustrating the arrangement relationship of the third heat sink and the spacers applied to the communication module according to the fourth embodiment.

FIG. 45 is a view illustrating a modified example of the third heat sink.

FIG. 46 is a view illustrating a communication module according to a fifth embodiment to which a third heat sink is applied.

FIG. 47 is a view illustrating another modified example of the third heat sink.

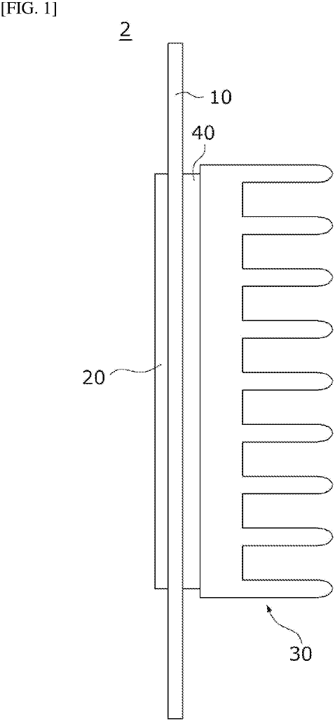

### MODES OF THE INVENTION

Hereinafter, exemplary embodiments of the present invention will be described in detail with reference the accompanying drawings.

However, the technical spirit of the present invention is not limited to some embodiments which will be described and may be embodied in a variety of different forms, and at least one or more components of the embodiments may be selectively combined, substituted, and used within the range of the technical spirit.

In addition, unless clearly and specifically defined otherwise by the context, all terms (including technical and scientific terms) used herein can be interpreted as having meanings customarily understood by those skilled in the art, and meanings of generally used terms, such as those defined in commonly used dictionaries, will be interpreted in consideration of contextual meanings of the related art.

In addition, the terms used in the embodiments of the present invention are considered in a descriptive sense only and not to limit the present invention.

In the present specification, unless clearly indicated otherwise by the context, singular forms include the plural forms thereof, and in a case in which “at least one (or one or more) among A, B, and C” is described, this may include at least one combination among all possible combinations of A, B, and C.

In addition, in descriptions of components of the present invention, terms such as “first,” “second,” “A,” “B,” “(a),” and “(b)” can be used.

The terms are only to distinguish one element from another element, and the essence, order, and the like of the elements are not limited by the terms.

In addition, it should be understood that, when an element is referred to as being “connected” or “coupled” to another element, such a description may include both a case in which the element is directly connected or coupled to another element, and a case in which the element is connected or coupled to another element with still another element disposed therebetween.

In addition, when any one element is described as being formed or disposed “on” or “under” another element, such a description includes both a case in which the two elements are formed or disposed in direct contact with each other and a case in which one or more other elements are interposed between the two elements. In addition, when one element is described as being formed “on or under” another element, such a description may include a case in which the one element is formed at an upper side or a lower side with respect to another element.

In an embodiment, a stacked structure for optimized heat dissipation may be implemented using the arrangement between a substrate having a hole formed therein, a communication unit, and a heat sink. For example, in the embodiment, unlike a conventional communication module, optimized heat dissipation performance may be secured by directly bringing a communication unit having a high heat generation amount and a heat sink into contact with each other.

Further, in the embodiment, a compact-sized communication module may be implemented by disposing some components in the hole formed in the substrate.

In addition, in the embodiment, a substrate of the communication unit may be electrically connected to the substrate having the hole formed therein using connectors. In this case, the connector may be a printed circuit board connector formed using a printed circuit board.

### First Embodiment

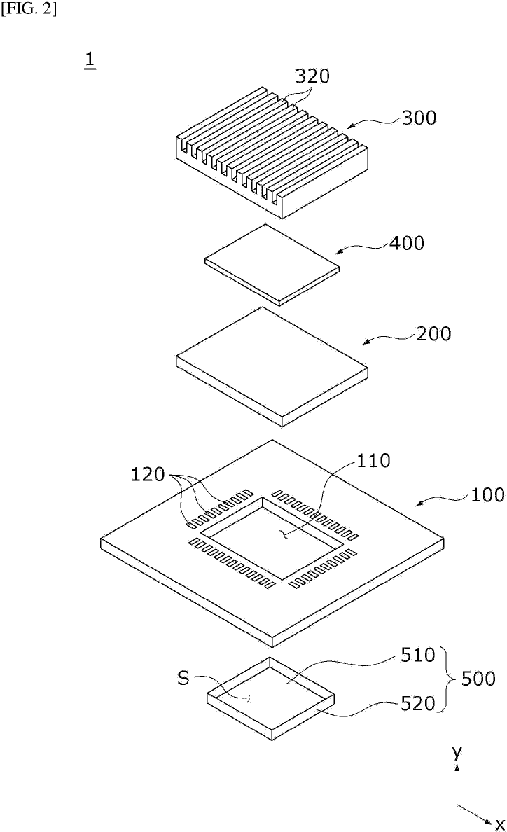

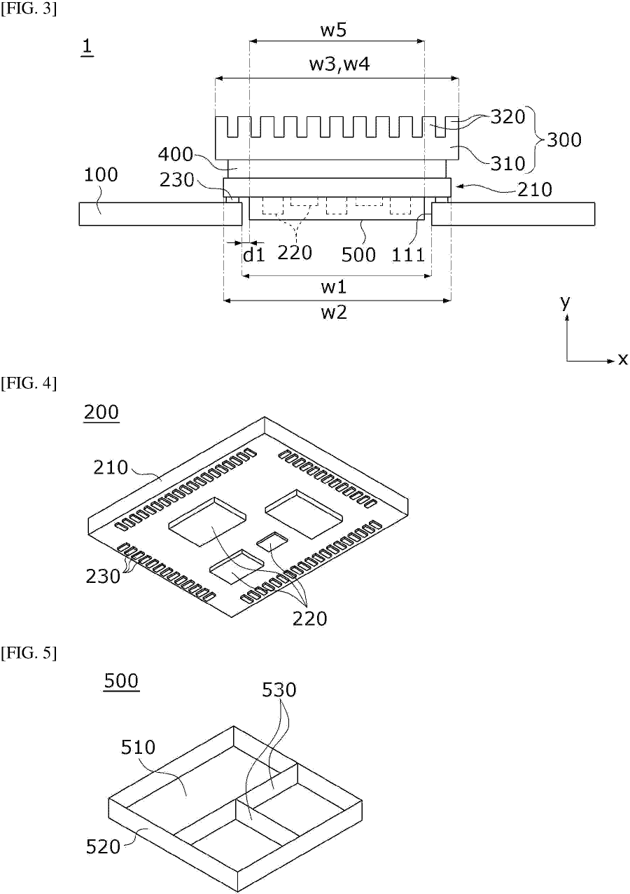

FIG. 2 is an exploded perspective view illustrating a communication module according to a first embodiment, FIG. 3 is a view illustrating the arrangement relationship of the communication module according to the first embodiment, FIG. 4 is a bottom perspective view illustrating a communication unit disposed in the communication module according to the first embodiment, and FIG. 5 is a view illustrating a modified example of a cover disposed in the communication module according to the first embodiment.

An x-direction shown in FIG. 2 may indicate a horizontal direction, and a y-direction shown in FIG. 2 may indicate a vertical direction. Here, the vertical direction may be referred to as a penetration direction or a stacking direction in consideration of the arrangement of a hole 110 formed in a first substrate 100. In this case, the horizontal direction and the vertical direction may be perpendicular to each other.

Referring to FIGS. 2 and 3, a communication module 1 according to the embodiment may include the first substrate 100 having the first hole 110 formed herein, a communication unit 200 including a second substrate 210 and a plurality of elements 220 disposed on one surface of the second substrate 210, and a heat sink 300 disposed on the other surface of the second substrate 210. Here, the other surface may be a surface opposite the one surface with respect to the second substrate 210. Further, the heat sink 300 may be referred to as a first heat sink.

Further, the communication module 1 according to the embodiment may further include a thermally conductive member 400 disposed between the heat sink 300 and the second substrate 210.

In addition, the communication module 1 according to the embodiment may further include a cover 500 disposed to cover the elements 220.

Accordingly, the communication module 1 may implement a stacked structure in which the first substrate 100, the communication unit 200, the thermally conductive member 400, and the heat sink 300 are stacked in a vertical direction. In this case, the cover 500 may be disposed in the first hole 110.

The first substrate 100 may be formed in a plate shape. Further, various substrates may be used as the first substrate 100. For example, a printed circuit board (PCB), a flexible substrate, a ceramic substrate, a glass substrate, and the like may be used as the first substrate 100.

Further, the first substrate 100 may be electrically connected to the communication unit 200. Here, the first substrate 100 may be referred to as a module substrate. Further, the first substrate 100 may be a multilayer substrate formed of a plurality of layers, and circuit patterns for forming an electrical connection may be formed between the layers.

Referring to FIGS. 2 and 3, the first substrate 100 may include the first hole 110 formed to pass therethrough in a vertical direction and a plurality of first terminals 120 disposed on an upper surface thereof, which is one surface. In this case, upper surfaces of the first terminals 120 may be disposed on the same plane as the upper surface of the first substrate 100.

Further, a plurality of electronic elements (not shown), a plurality of electrodes (not shown), line patterns (not shown), and the like in addition to the first terminals 120 may be disposed on the first substrate 100.

The first hole 110 may be formed in the first substrate 100 to pass through the first substrate 100 in the vertical direction. As the first hole 110 is formed, the first substrate 100 may include an inner surface 111 for forming the first hole 110. Here, as shown in FIG. 2, an example in which the first hole 110 is formed in a quadrangular shape is described, but the present invention is not necessarily limited thereto.

The first terminals 120 may be formed on one surface of the first substrate 100.

For example, the first terminals 120 may be disposed to face the second substrate 210. As shown in FIG. 2, the first terminals 120 may be formed on the upper surface of the first substrate 100. In this case, the first terminals 120 may be formed on the first substrate 100 to be exposed for an electrical connection with the communication unit 200.

Further, the plurality of first terminals 120 may be formed to be spaced apart from each other along a periphery of the first hole 110, and may be provided as components electrically connected to the communication unit 200.

Referring to FIGS. 2 to 4, the communication unit 200 may include the second substrate 210, the plurality of elements 220 disposed on the second substrate 210, and a plurality of pads 230 disposed on the second substrate 210.

In this case, in consideration of a contact relationship between the communication unit 200 and the first substrate 100 and a contact relationship between the communication unit 200 and the heat sink 300, arrangement positions of the elements 220 and the pads 230 may be changed. Accordingly, the communication module 1 may be provided in a compact size by implementing various stacked structures in consideration of the positions of the elements 220 and the pads 230.

Various substrates may be used as the second substrate 210. For example, a printed circuit board (PCB), a flexible substrate, a ceramic substrate, a glass substrate, and the like may be used as the second substrate 210.

Further, the second substrate 210 may be electrically connected to the first substrate 100 through the pads 230. Here, the second substrate 210 may be referred to as a unit substrate. Further, the second substrate 210 may be a multilayer substrate formed of a plurality of layers, and circuit patterns for forming an electrical connection may be formed between the layers.

An area of the second substrate 210 may be larger than an area of the first hole 110. For example, a horizontal width W2 of the second substrate 210 may be larger than a horizontal width W1 of the first hole 110. Here, the horizontal width W1 of the first hole 110 may be referred to as a first width, and the horizontal width W2 of the second substrate 210 may be referred to as a second width.

Further, the second substrate 210 may be disposed at an upper side of the first substrate 100 to cover the upper side, which is one side of the first hole 110. Accordingly, an edge region of one surface of the second substrate 210 may be disposed to vertically overlap a peripheral region of the first hole 110 of the first substrate 100. Specifically, the peripheral region of the first substrate 100 having the first hole 110 formed therein is disposed to overlap the edge region of the second substrate 210, and the first terminals 120 disposed in the peripheral region may be electrically connected to the pads 230 disposed in the edge region.

In consideration of the contact relationship between the second substrate 210 and the heat sink 300 and arrangement interference with the first substrate 100, the elements 220 may be disposed only on one surface at a lower side of the second substrate 210.

As shown in FIG. 3, the elements 220 may be disposed on a lower surface of the second substrate 210. In this case, some regions of the elements 220 may be disposed in the first hole 110. Accordingly, the elements 220 may be protected by the first substrate 100.

Accordingly, a vertical size of the communication unit 200 may be reduced compared to a case in which the elements 220 are disposed on both surfaces of the second substrate 210.

Further, since the heat sink 300 may be disposed on the other surface opposite to the one surface on which the elements 220 are disposed, the amount of contact between the second substrate 210 and the heat sink 300 may be improved. Accordingly, the communication module 1 may effectively dissipate heat.

Meanwhile, the elements 220 may include various elements such as active elements and passive elements, and the active elements may include communication elements used for communication. For example, the element 220 may be an electronic element related to a network access device (NAD), an electronic element related to WIFI, an electronic element related to Bluetooth (BT) communication, a power amplifier, a front end module (FEM) element having a built-in power amplifier, a radio frequency (RF) filter, or the like.

Specifically, since the electronic element related to the network access device (NAD) has a greater heat generation amount compared to other elements, the communication module 1 may effectively dissipate heat generated in the electronic element related to the network access device (NAD) by implementing a stacked structure through the first hole 110. For example, a structure in which the elements 220 are disposed on the lower surface of the second substrate 210 and the heat sink 300 is disposed on the upper surface, which is the other surface, and a structure in which the elements 220 are disposed in the first hole 110 may improve the heat dissipation performance of the elements 220.

Further, the plurality of elements 220 may be separately disposed in respective spaces partitioned by a blocking sidewall of the cover 500 to be described below.

The pads 230 may be disposed on the same surface as the surface of the second substrate 210 on which the elements 220 are disposed. As shown in FIG. 3, the pads 230 may be disposed on the lower surface of the second substrate 210 to be spaced apart from the elements 220.

The plurality of pads 230 may be disposed to be spaced apart from each other along the edge region of the lower surface of the second substrate 210.

Here, the pads 230 may be disposed to face the first terminals 120 of the first substrate 100. Accordingly, when the second substrate 210 is disposed at an upper side of the first substrate 100, the first terminals 120 may come into contact with the pads 230. In this case, the first terminal 120 may be formed to have the same area as the pad 230, but the present invention is not limited thereto. For example, an area of the first terminal 120 in the horizontal direction may be larger than an area of the pad 230 in the horizontal direction in consideration of contactability.

Further, the pads 230 and the first terminals 120 may be welded and bonded together using spot welding using a laser, or may be electrically and physically bonded through a conductive adhesive such as a solder.

In addition, the pads 230 may be formed to protrude from the lower surface of the second substrate 210. The plurality of pads 230 may be disposed to be spaced apart from each other. Accordingly, a space is formed between the pads 230, and the space may be provided as a heat dissipation path through which the heat generated in the elements 220 is discharged.

Meanwhile, the number of the pads 230 may be the same as the number of the first terminals 120, but the present invention is not limited thereto.

The heat sink 300 may dissipate the heat generated in the elements 220 and transferred to the second substrate 210.

Here, the heat sink 300 may be formed of a material having high thermal conductivity and capable of shielding electromagnetic waves. For example, an alloy of copper, aluminum, zinc, and nickel may be used as the material of the heat sink 300, but the present invention is not limited thereto.

The heat sink 300 may include a body 310 and a plurality of heat dissipation fins 320 formed to protrude from an upper surface, which is one surface of the body 310. Here, the body 310 and the heat dissipation fins 320 may be integrally formed.

The body 310 may be formed in a flat plate shape. In this case, a horizontal width W3 of the body 310 may be larger than the horizontal width W2 of the second substrate 210. Accordingly, the heat dissipation performance of the heat sink 300 may be improved. Here, the horizontal width W3 of the body 310 may be referred to as a third width.

Further, a lower surface, which is the other surface of the body 310, may come into contact with the upper surface of the second substrate 210 through the thermally conductive member 400.

The plurality of heat dissipation fins 320 may be formed to be spaced apart from each other on the upper surface of the body 310, and the plurality of heat dissipation fins 320 may be formed to have a predetermined width W4 in the horizontal direction. In this case, the horizontal width W4 of the plurality of heat dissipation fins 320 may be smaller than or equal to the horizontal width W3 of the body 310. Here, the horizontal width W4 of the plurality of heat dissipation fins 320 may be referred to as a fourth width.

The thermally conductive member 400 may be disposed between the heat sink 300 and the second substrate 210. Accordingly, the thermally conductive member 400 may transfer the heat of the second substrate 210 to the heat sink 300. In this case, the thermally conductive member 400 may be disposed on the second substrate 210.

Further, the thermally conductive member 400 may be formed of a material having high thermal conductivity. For example, a liquid type such as paste or grease, a sheet type, and a pad type formed of silicon or the like may be selectively used as the thermally conductive member 400.

The cover 500 may be disposed to cover the elements 220. Here, the cover 500 may be formed of a material having high thermal conductivity and capable of shielding electromagnetic waves. For example, an alloy of copper, zinc, and nickel may be used as the material of the cover 500, but the present invention is not limited thereto.

Further, an entire region or a partial region of the cover 500 may be disposed in the first hole 110.

Referring to FIGS. 2 and 3, the cover 500 may include a plate part 510 and a sidewall 520 protruding from the plate part 510. Accordingly, a cavity S where the elements 220 may be disposed may be formed in the cover 500.

The plate part 510 and the sidewall 520 may be integrally formed. For example, the cavity may be formed in the cover 500 by processing a flat metal plate with a pressing device (not shown).

The plate part 510 may be formed in a plate shape, and may be disposed in the first hole 110.

The sidewall 520 may be disposed to be spaced apart from the inner surface 111 of the first substrate 100 forming the first hole 110 by a predetermined distance d1. Accordingly, a space may be formed between the sidewall 520 and the inner surface 111, and the space may be provided as a heat dissipation path through which the heat generated in the elements 220 is discharged.

That is, since a horizontal width W5 of the cover 500 may be smaller than the horizontal width W1 of the first hole 110, the heat dissipation path may be formed between the sidewall 520 and the inner surface 111. Here, the width W5 may be referred to as a fifth width.

Referring to FIG. 5, the cover 500 may further include a blocking sidewall 530 protruding from the plate part 510.

The blocking sidewall 530 may be formed in the cavity and may be disposed between the plurality of elements 220. Accordingly, the blocking sidewall 530 may prevent electromagnetic waves generated in one element 220 from affecting other elements 220.

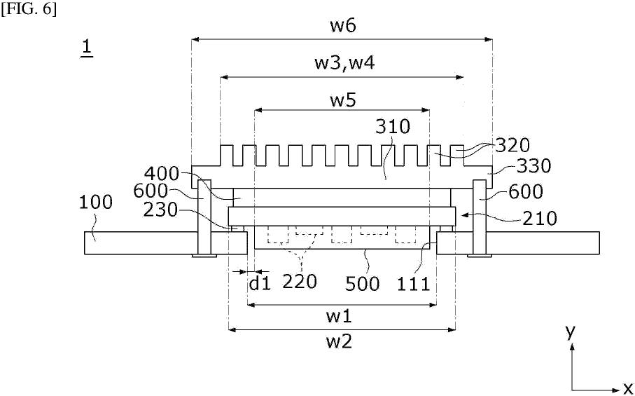

FIG. 6 is a view illustrating a coupling relationship by fastening members of the communication module according to the first embodiment.

Referring to FIG. 6, the heat sink 300 may further include a first protrusion 330, which elongates the body 310 in the horizontal direction. Accordingly, the heat sink 300 may have a width W6 further extending in the horizontal direction from the width W3 in the horizontal direction of the body 310 due to the first protrusion 330. Here, the width W6 may be referred to as a sixth width.

Further, the first substrate 100 and the first protrusion 330 may be coupled by fastening members 600. Accordingly, the second substrate 210 may be firmly fixed by coming into close contact with the first substrate 100. Further, adhesion of the thermally conductive member 400 may also be improved by the coupling.

Here, the first substrate 100 may have a through hole formed therein for coupling with the fastening members 600. Further, the first protrusion 330 may have a through hole or a groove formed therein for coupling with the fastening members 600.

### Second Embodiment

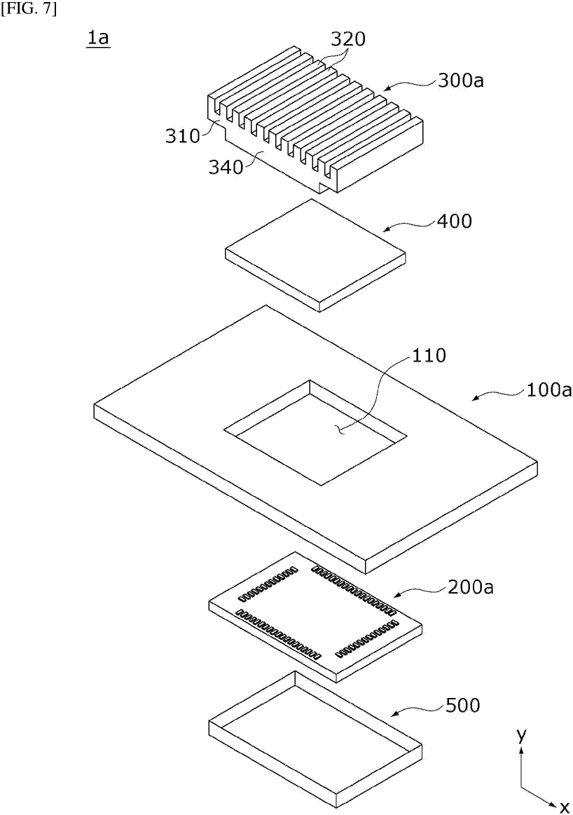

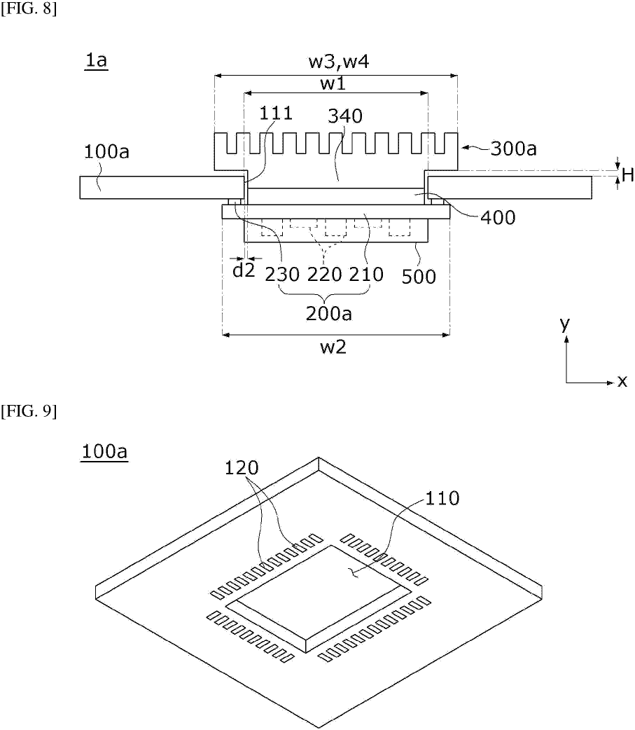

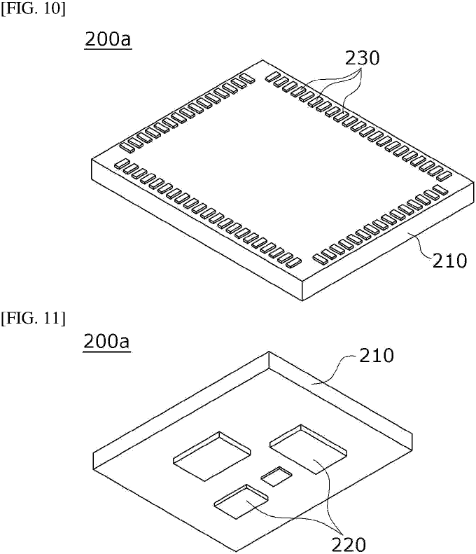

FIG. 7 is an exploded perspective view illustrating a communication module according to a second embodiment, FIG. 8 is a view illustrating the arrangement relationship of the communication module according to the second embodiment, FIG. 9 is a bottom perspective view illustrating a first substrate disposed in the communication module according to the second embodiment, FIG. 10 is a perspective view illustrating a communication unit disposed in the communication module according to the second embodiment, and FIG. 11 is a bottom perspective view illustrating the communication unit disposed in the communication module according to the second embodiment.

In a description of a communication module 1a according to the second embodiment with reference to FIGS. 7 and 11, since components the same as those of the communication module 1 according to the first embodiment may be described with the same drawing numerals, detailed descriptions thereof will be omitted.

When comparing the communication module 1 according to the first embodiment and the communication module 1a according to the second embodiment, the communication module 1a according to the second embodiment has a difference in that arrangement positions of a communication unit 200a and a heat sink 300a are different, and accordingly, a shape of each component of the communication module 1a according to the second embodiment is changed. Further, there is a difference in that a portion of the heat sink 300a and a thermally conductive member 400 are disposed in a first hole 110. Here, the heat sink 300a may be referred to as a second heat sink.

However, the communication module 1a according to the second embodiment may share a case in which an edge region of a second substrate 210 of the communication unit 200a is disposed to vertically overlap a periphery of the first hole 110 of a first substrate 100a with the communication module 1 according to the first embodiment.

Referring to FIGS. 7 and 8, the communication module 1a according to the second embodiment may include the first substrate 100a having the first hole 110 formed herein, the communication unit 200a disposed at a lower side of the first substrate 100a, the heat sink 300a disposed at an upper side of the first substrate 100a, the thermally conductive member 400 disposed in the hole 110 to thermally connect the second substrate 210 of the communication unit 200a and the heat sink 300a, and a cover 500 disposed to cover elements of the communication unit 200a.

Referring to FIG. 9, the first substrate 100a may include the first hole 110 formed to pass therethrough in a vertical direction and a plurality of first terminals 120 disposed on a lower surface thereof, which is one surface.

That is, when comparing the first substrate 100 of the communication module 1 according to the first embodiment and the first substrate 100a of the communication module 1a according to the second embodiment, the first substrate 100 of the communication module 1 according to the first embodiment and the first substrate 100a of the communication module 1a according to the second embodiment have a difference in arrangement positions of the first terminals 120.

Referring to FIGS. 10 and 11, the communication unit 200a may include the second substrate 210, a plurality of elements 220 disposed on a lower surface of the second substrate 210, and a plurality of pads 230 disposed on an upper surface of the second substrate 210.

That is, when comparing the communication unit 200 of the communication module 1 according to the first embodiment and the communication unit 200a of the communication module 1a according to the second embodiment, the communication unit 200 of the communication module 1 according to the first embodiment and the communication unit 200a of the communication module 1a according to the second embodiment have a difference in arrangement positions of the pads 230. This is for disposing the pads 230 to face the first terminals 120 of the communication module 1a according to the second embodiment.

Referring to FIGS. 7 and 8, the heat sink 300a may include a body 310, a plurality of heat dissipation fins 320 formed to protrude from an upper surface, which is one surface of the body 310, and a second protrusion 340 formed to protrude from a lower surface, which is the other surface of the body 310. Accordingly, the thermally conductive member 400 may be disposed between the second protrusion 340 and the second substrate 210.

That is, when comparing the heat sink 300 of the communication module 1 according to the first embodiment and the heat sink 300a of the communication module 1a according to the second embodiment, the heat sink 300 of the communication module 1 according to the first embodiment and the heat sink 300a of the communication module 1a according to the second embodiment have a difference in whether the second protrusion 340 is formed.

Referring to FIG. 8, a portion of the second protrusion 340 may be disposed in the first hole 110 together with the thermally conductive member 400. In this case, the second protrusion 340 and the thermally conductive member 400 may be disposed to be spaced apart from an inner surface 111 of the first substrate 100a forming the first hole 110 by a predetermined distance d2. Accordingly, a first space may be formed between the second protrusion 340 and the inner surface 111 and between the thermally conductive member 400 and the inner surface 111, and the first space may be provided as a heat dissipation path through which heat is discharged.

Meanwhile, the body 310 may be disposed to come into contact with the first substrate 100a or to be spaced apart from the first substrate 100a by a predetermined height H according to length of the second protrusion 340 in the vertical direction.

As shown in FIG. 8, when the body 310 is disposed to be spaced apart from an upper surface of the first substrate 100a by the predetermined height H, a second space may be formed between the upper surface of the first substrate 100a and the body 310, and the second space may be formed to communicate with the first space. Accordingly, since the first space and the second space are provided as heat dissipation paths through which heat is discharged, the heat dissipation performance of the communication module 1a may be improved.

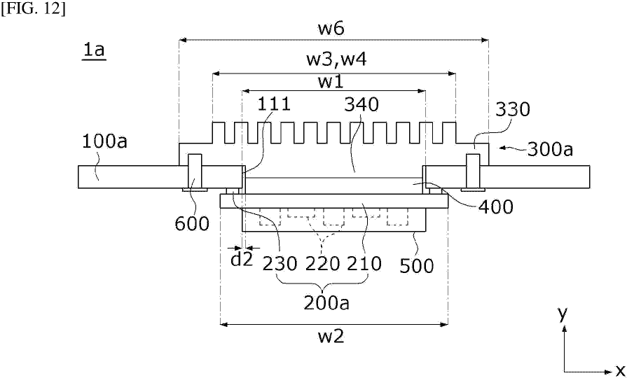

FIG. 12 is a view illustrating a coupling relationship by fastening members of the communication module according to the second embodiment.

Referring to FIG. 12, the heat sink 300a may further include a first protrusion 330, which elongates the body 310 in the horizontal direction. Accordingly, the heat sink 300a may have a width W6 further extending in the horizontal direction from the width W3 in the horizontal direction of the body 310 due to the first protrusion 330.

Further, the first substrate 100a and the first protrusion 330 may be coupled by fastening members 600. Here, the first substrate 100 may have a through hole formed therein for coupling with the fastening members 600. Further, the first protrusion 330 may have a through hole or a groove formed therein for coupling with the fastening members 600.

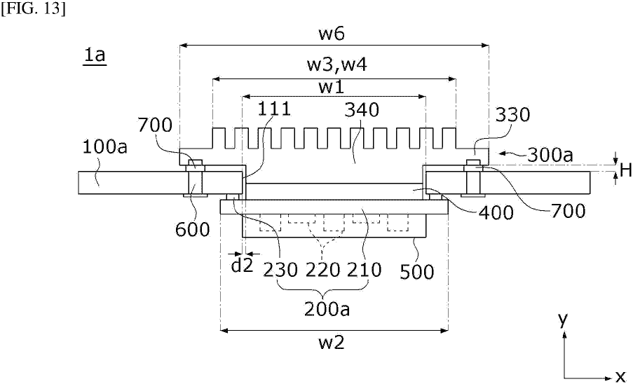

FIG. 13 is a view illustrating spacers of the communication module according to the second embodiment.

Referring to FIG. 13, the communication module 1a may further include spacers 700, which dispose the first substrate 100a and the first protrusion 330 so that the first substrate 100a and the first protrusion 330 are spaced apart from each other by a predetermined distance.

Due to the spacers 700, predetermined spaces between the first substrate 100a and the first protrusions 330 may be secured, and heat dissipation paths through which heat is discharged may be secured.

Further, when the first substrate 100a and the first protrusion 330 are coupled by the fastening members 600, the spacers 700 may serve as buffer members.

### Third Embodiment

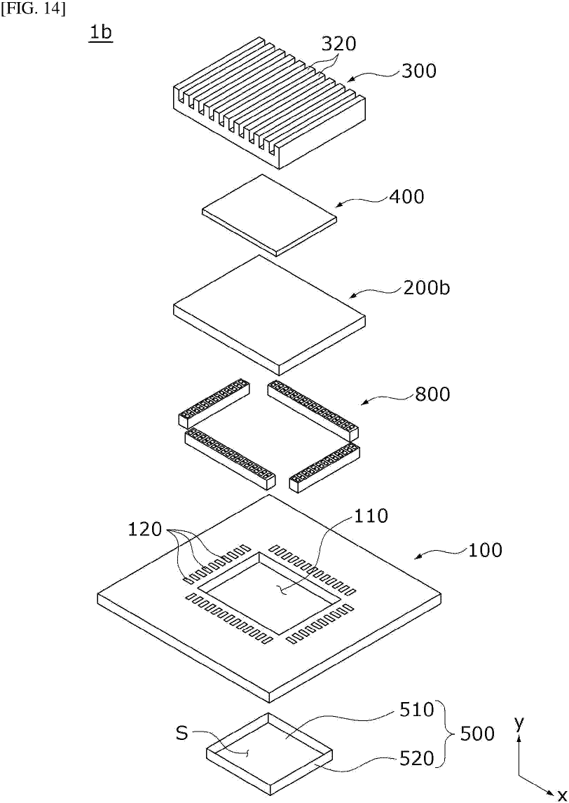

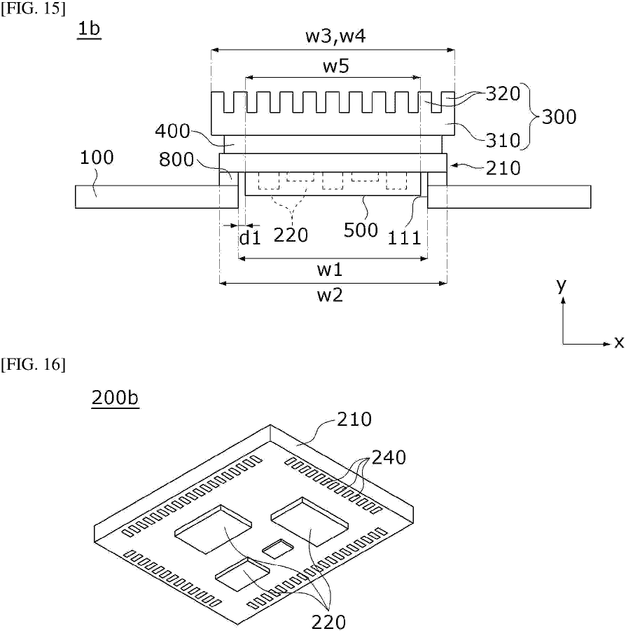

FIG. 14 is an exploded perspective view illustrating a communication module according to a third embodiment, and FIG. 15 is a view illustrating the arrangement relationship of the communication module according to the third embodiment.

In a description of a communication module 1b according to the third embodiment with reference to FIGS. 14 and 15, since components the same as those of the communication module 1 according to the first embodiment may be described with the same drawing numerals, detailed descriptions thereof will be omitted.

When comparing the communication module 1 according to the first embodiment and the communication module 1b according to the third embodiment, the communication module 1b according to the third embodiment has a difference in that second terminals 240 formed on a second substrate 210 are included instead of the pads 230 of the communication module 1 according to the first embodiment, and a first substrate 100 and the second substrate 210 are electrically connected by connectors 800.

However, the communication module 1b according to the third embodiment may share a case in which an edge region of the second substrate 210 of a communication unit 200b is disposed to vertically overlap a periphery of the first hole 110 of the first substrate 100a with the communication module 1 according to the first embodiment.

Referring to FIGS. 14 and 15, the communication module 1b according to the third embodiment may include the first substrate 100 having the first hole 110 formed herein, the communication unit 200b including the second substrate 210 and a plurality of elements 220 and a plurality of second terminals 240 disposed on one surface of the second substrate 210, a heat sink 300 disposed on the other surface of the second substrate 210, a thermally conductive member 400 disposed between the heat sink 300 and the second substrate 210, a cover 500 disposed to cover the elements 220 of the communication unit 200b, and the connectors 800 which electrically connect the first substrate 100 and the second substrate 210.

FIG. 16 is a bottom perspective view illustrating a communication unit disposed in the communication module according to the first embodiment.

Referring to FIG. 16, the communication unit 200b may include the second substrate 210, the plurality of elements 220 disposed on the second substrate 210, and the plurality of second terminals 240 disposed on the second substrate 210.

The second terminals 240 may be formed on a lower surface of the second substrate 210. In this case, the second terminals 240 may be formed on the second substrate 210 to be exposed for an electrical connection with the connectors 800.

Referring to FIGS. 14 and 15, the connectors 800 may be disposed between first terminals 120 formed on the first substrate 100 and the second terminals 240 formed on the second substrate 210. Accordingly, the connectors 800 may electrically connect the first substrate 100 and the communication unit 200b.

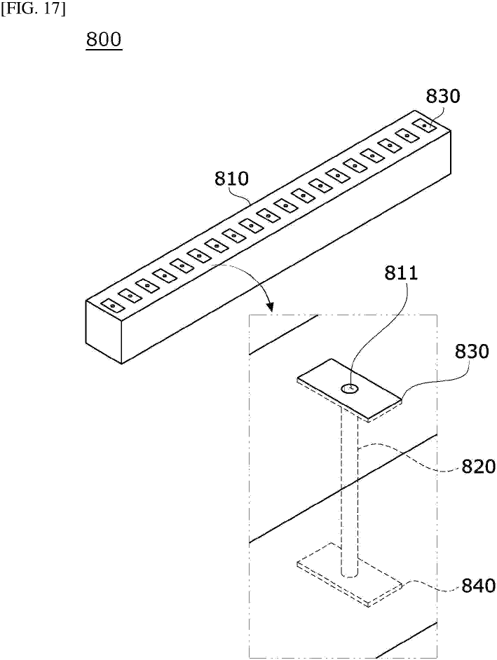

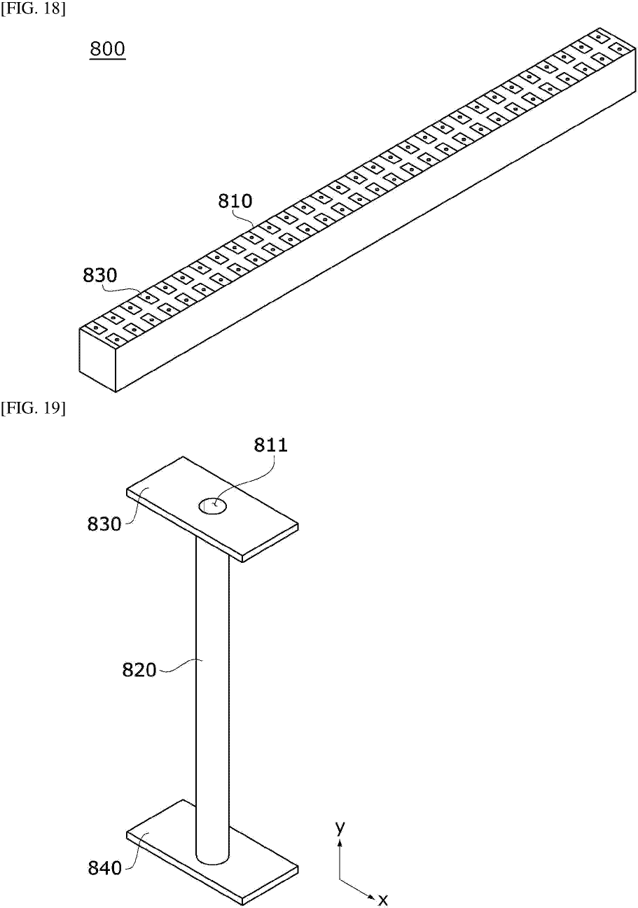

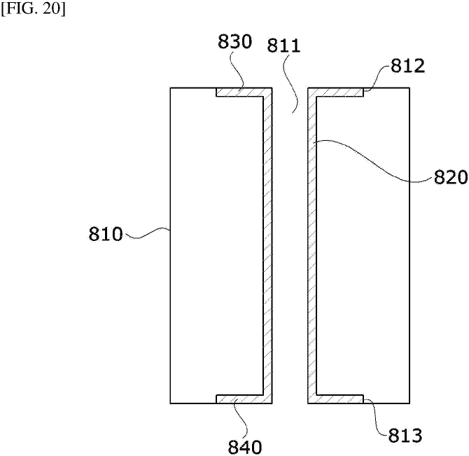

FIG. 17 is a view illustrating a connector according to a first embodiment disposed in the communication module according to the third embodiment, FIG. 18 is a view illustrating a modified example of the connector according to the first embodiment disposed in the communication module according to the third embodiment, and FIGS. 19 and 20 are views illustrating shapes of a metal layer and a metal pad of the connector according to the first embodiment disposed in the communication module according to the third embodiment.

Referring to FIGS. 17 to 20, the connector 800 according to the first embodiment may include a third substrate 810 having second holes 811 formed therein, metal layers 820 disposed in the second holes 811, first metal pads 830, and second metal pads 840. Here, the metal layers 820 disposed in the second holes 811 may be referred to as first metal layers.

The third substrate 810 may be formed of an insulating material, and the insulating material may include, for example, epoxy or the like and may be an insulating material of 106 MΩ or more. For example, a printed circuit board (PCB), a flexible substrate, a ceramic substrate, a glass substrate, and the like may be used as the third substrate 810.

The third substrate 810 may be formed in a bar shape. The third substrate 810 may be formed to be smaller than the substrate to be electrically connected, and may be disposed in an edge portion of the second substrate 210.

The second holes 811 may be formed in the third substrate 810 at predetermined intervals. As shown in FIG. 17, the second holes 811 may be formed in one row. Alternatively, as shown in FIG. 18, the second holes 811 may be formed in two rows. In this case, a diameter of each of the holes may range from 0.3 to 0.5 mm.

As shown in FIG. 17, when the second holes 811 are formed in one row, the second holes 811 may be formed in a center portion of the third substrate 810, but are not limited thereto, and may be formed in an edge portion of the third substrate 810. Further, the second holes 811 may be formed in one row, two rows, or three or more rows.

As shown in FIG. 18, when the second holes 811 are formed in two rows, a case in which the second holes 811 implemented in two rows are disposed in parallel is shown, but the present invention is not limited thereto. For example, the second holes 811 implemented in two rows may be disposed in a zigzag shape.

Further, a metal layer 820 coated with a metal material may be formed on an inner circumferential surface of the second hole 811. Here, the metal material may be a conductive material. For example, the metal layer 820 may include copper (Cu), silver (Ag), or the like.

Further, the first metal pads 830 and the second metal pads 840 may be formed of a conductive material.

The first metal pad 830 may be formed at one end of the second hole 811 and may be connected to the metal layer 820. Further, the first metal pads 830 may be welded and bonded to the second terminals 240 of the second substrate 210 using spot welding using a laser, or may be electrically and physically bonded through a conductive adhesive such as a solder.

The second metal pad 840 may be formed at the other end of the second hole 811 and may be connected to the metal layer 820. Further, the second metal pads 840 may be welded and bonded to the first terminals 120 of the first substrate 100 using spot welding using a laser, or may be electrically and physically bonded through a conductive adhesive such as a solder.

In addition, the first metal pads 830 and the second metal pads 840 may be formed to correspond one-to-one.

Here, although an example in which the first metal pad 830 and the second metal pad 840 have the same size and shape is described, the present invention is not limited thereto, and the sizes or shapes may be changed as necessary.

Referring to FIG. 19, the first metal pad 830 and the second metal pad 840 may be connected to the metal layer 820 formed on the inner circumferential surface of the second hole 811. Here, although an example in which a cross-section of the second hole 811 has a circular shape is described, the present invention is not limited thereto, and various shapes may be applied. For example, cross-sectional shapes of the second hole 811 may include an oval shape, a polygonal shape, and the like.

The first metal pad 830, the second metal pad 840, and the metal layer 820 may be integrally formed.

Referring to FIG. 20, the first metal pad 830 may be formed on an upper surface, which is a first surface of the third substrate 810, and may be formed in a groove 812 concavely formed in a direction perpendicular to the first surface of the third substrate 810. Accordingly, the third substrate 810 may include a first seating surface formed so that the first metal pad 830 may be seated thereon. Accordingly, one surface of the first metal pad 830 may be located on the same plane as the first surface of the third substrate 810.

Likewise, the second metal pad 840 may be formed on a second surface, which is a lower surface of the third substrate 810, and may be formed in a groove 813 concavely formed in a direction perpendicular to the second surface of the third substrate 810. Accordingly, the third substrate 810 may include a second seating surface formed so that the second metal pad 840 may be seated thereon. Accordingly, one surface of the second metal pad 840 may be located on the same plane as the second surface of the third substrate 810.

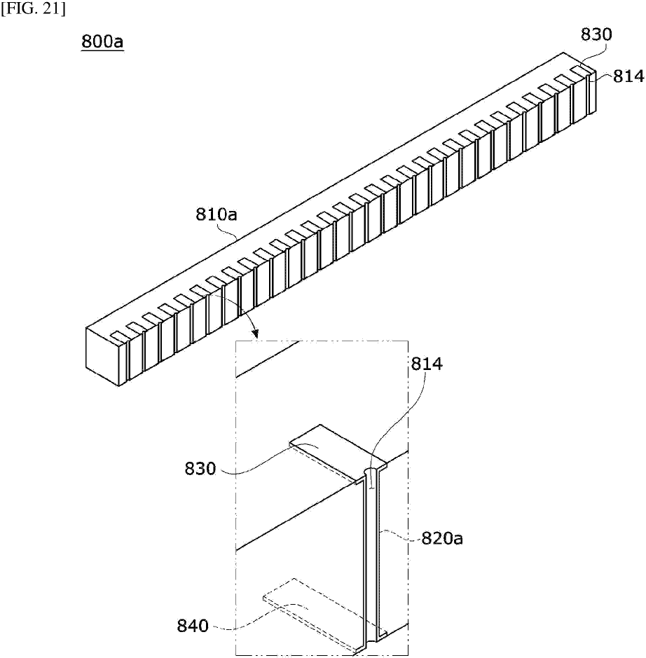

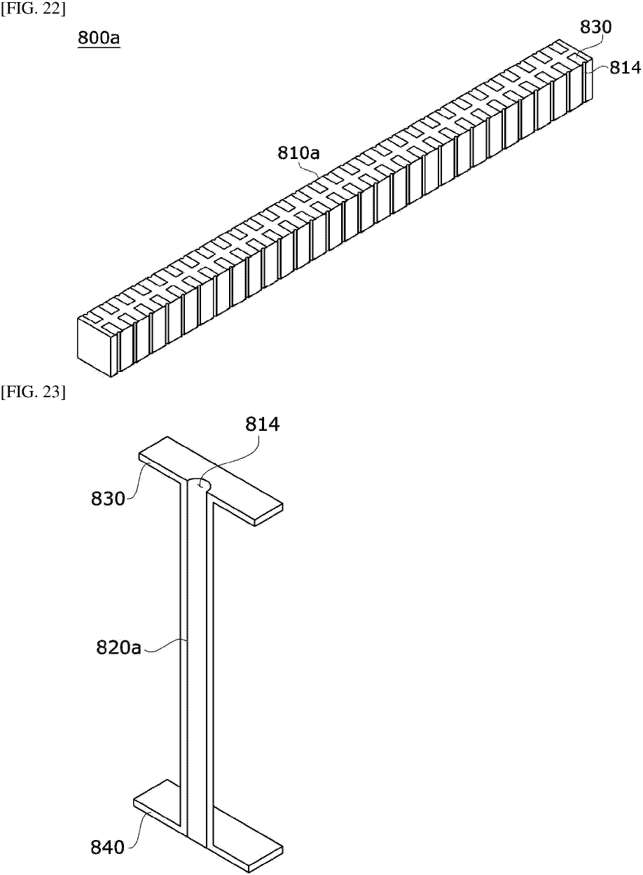

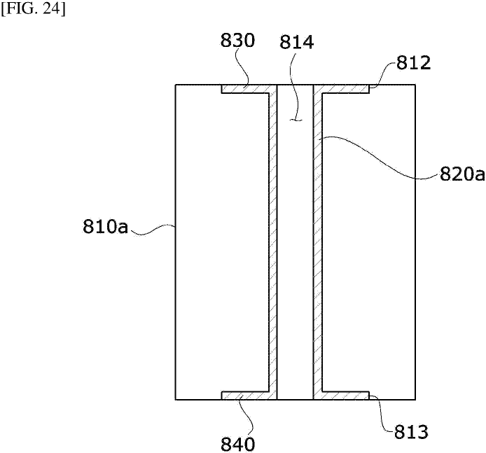

FIG. 21 is a view illustrating a connector according to a second embodiment disposed in the communication module according to the third embodiment, FIG. 22 is a view illustrating a modified example of the connector according to the second embodiment disposed in the communication module according to the third embodiment, and FIGS. 23 and 24 are views illustrating shapes of a metal layer and a metal pad of the connector according to the second embodiment disposed in the communication module according to the third embodiment.

Referring to FIGS. 21 to 24, a connector 800a according to the second embodiment includes a third substrate 810a having grooves 814 concavely formed in at least one surface, metal layers 820a disposed in the grooves 814, first metal pads 830, and second metal pads 840. Here, the metal layers 820 disposed in the grooves 814 may be referred to as second metal layers.

The third substrate 810a may be formed of an insulating material, and the insulating material may include, for example, epoxy or the like and may be an insulating material of 106 MΩ or more. For example, a printed circuit board (PCB), a flexible substrate, a ceramic substrate, a glass substrate, and the like may be used as the third substrate 810a.

The third substrate 810a may be formed in a bar shape. The third substrate 810a may be formed to be smaller than the substrate to be electrically connected, and may be disposed in an edge portion of the second substrate 210.

The grooves 814 may be formed in the third substrate 810 at predetermined intervals. As shown in FIG. 21, the grooves 814 may be formed in one row. Alternatively, as shown in FIG. 22, the grooves 814 may be formed in two rows. In this case, the grooves 814 may be concavely formed in any one of side surfaces of the third substrate 810 in a horizontal direction.

As shown in FIG. 21, when the grooves 814 are formed in one row, the grooves 814 may be formed in the side surface disposed toward a center of the first hole 110 among the side surfaces of the third substrate 810, but are not limited thereto, and may be formed in another edge portion. Further, the grooves 814 may be formed in one row, two rows, or three or more rows.

As shown in FIG. 22, when the grooves 814 are formed in two rows, FIG. 22 illustrates a case in which the grooves 814 implemented in two rows are disposed in parallel, but the present invention is not limited thereto. For example, the grooves 814 implemented in two rows may be disposed in the third substrate 810 in a zigzag shape.

Further, the metal layer 820a coated with a metal material may be formed on an inner surface of the groove 814.

The first metal pad 830 may be formed at one end of the groove 814 and may be connected to the metal layer 820a. Further, the first metal pads 830 may be welded and bonded to the second terminals 240 of the second substrate 210 using spot welding using a laser, or may be electrically and physically bonded through a conductive adhesive such as a solder.

The second metal pad 840 may be formed at the other end of the groove 814 and may be connected to the metal layer 820a. In this case, the first metal pads 830 and the second metal pads 840 may be formed of a conductive material. Further, the second metal pads 840 may be welded and bonded to the first terminals 120 of the first substrate 100 using spot welding using a laser, or may be electrically and physically bonded through a conductive adhesive such as a solder.

In addition, the first metal pads 830 and the second metal pads 840 may be formed to correspond one-to-one.

Here, although an example in which the first metal pad 830 and the second metal pad 840 have the same size and shape is described, the present invention is not limited thereto, and the sizes or shapes may be changed as necessary.

Referring to FIG. 23, the first metal pad 830 and the second metal pad 840 may be connected to the metal layer 820a formed on the inner surface of the second groove 814. Here, although an example in which a cross-section of the second hole 811 has a semicircular shape is shown, the present invention is not limited thereto, and various shapes may be applied. For example, cross-sectional shapes of the second hole 811 may include a semi-elliptical shape, a polygonal shape, and the like.

Meanwhile, the first metal pad 830, the second metal pad 840, and the metal layer 820a may be integrally formed.

Referring to FIG. 24, the first metal pad 830 may be formed on an upper surface, which is a first surface of the third substrate 810, and may be formed in a groove 812 concavely formed in a direction perpendicular to the first surface of the third substrate 810. Accordingly, the third substrate 810 may include a first seating surface formed so that the first metal pad 830 may be seated thereon. Accordingly, one surface of the first metal pad 830 may be located on the same plane as the first surface of the third substrate 810.

Likewise, the second metal pad 840 may be formed on a second surface, which is a lower surface of the third substrate 810, and may be formed in a groove 813 formed in a direction perpendicular to the second surface of the third substrate 810. Accordingly, the third substrate 810 may include a second seating surface formed so that the second metal pad 840 may be seated thereon. Accordingly, one surface of the second metal pad 840 may be located on the same plane as the second surface of the third substrate 810.

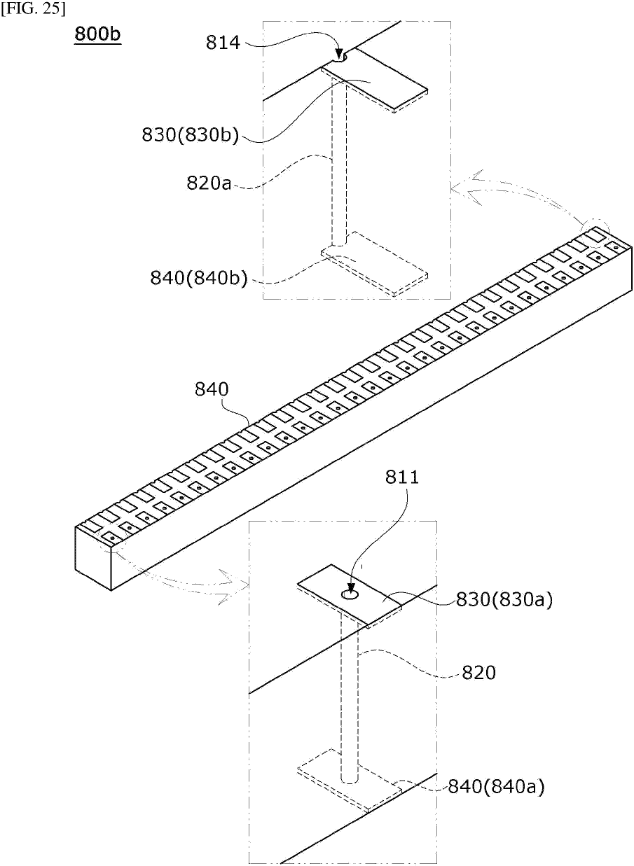

FIG. 25 is a view illustrating shapes of a metal layer and a metal pad of a connector according to a third embodiment disposed in the communication module according to the third embodiment.

Referring to FIG. 25, a connector 800b according to the third embodiment may include a third substrate 810 having second holes 811 and grooves 814 formed therein, metal layers 820 and 820a disposed in the second hole 811 and the groove 814, first metal pads 830, and second metal pads 840.

Here, the first metal pad 830 may include a first-1 metal pad 830a connected to the metal layer 820 disposed in the second hole 811, and the second metal pad 840 may include a second-1 metal pad 840a connected to the metal layer 820 disposed in the second hole 811. Further, the first metal pad 830 may include a first-2 metal pad 830b connected to the metal layer 820a disposed in the groove 814, and the second metal pad 840 may include a second-2 metal pads 840b connected to the metal layer 820a disposed in the groove 814.

As shown in FIG. 25, the connector 800b according to the third embodiment shows a case in which the second holes 811 and the grooves 814 are each formed in one row, and accordingly, the first substrate 100 and the second substrate 210 may be electrically connected to each other.

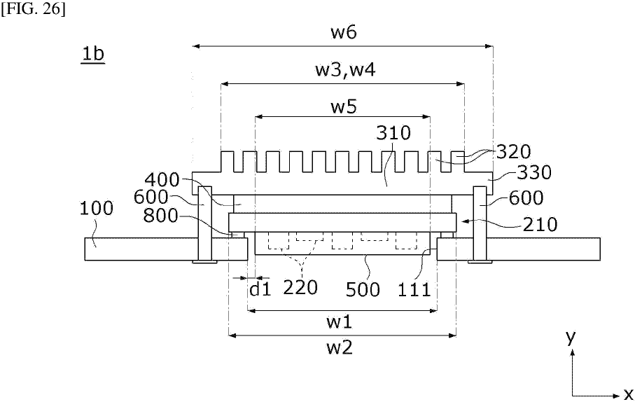

FIG. 26 is a view illustrating a coupling relationship by fastening members of the communication module according to the third embodiment.

Referring to FIG. 26, the heat sink 300 may further include a first protrusion 330, which elongates the body 310 in the horizontal direction. Accordingly, the heat sink 300 may have a width W6 further extending in the horizontal direction from a width W3 in the horizontal direction of the body 310 due to the first protrusion 330.

Further, the first substrate 100 and the first protrusion 330 may be coupled by fastening members 600. Accordingly, the second substrate 210 may be firmly fixed by coming into close contact with the first substrate 100. Further, adhesion of the thermally conductive member 400 may also be improved by the coupling.

### Fourth Embodiment

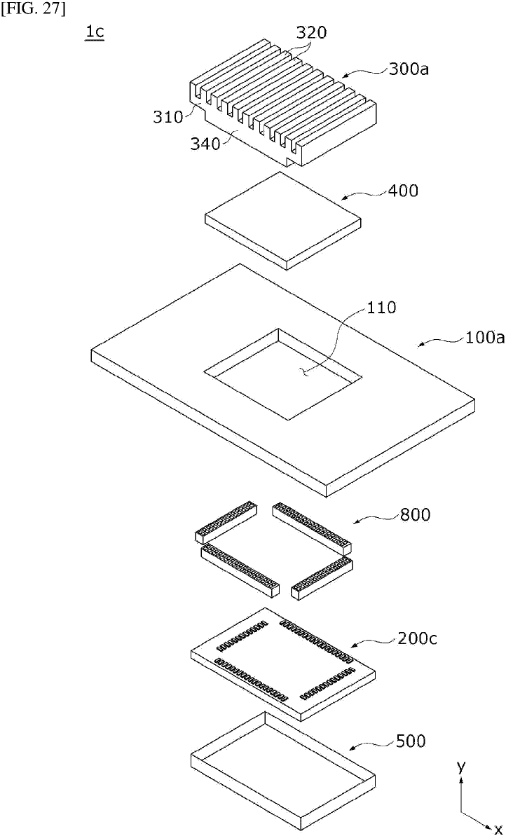

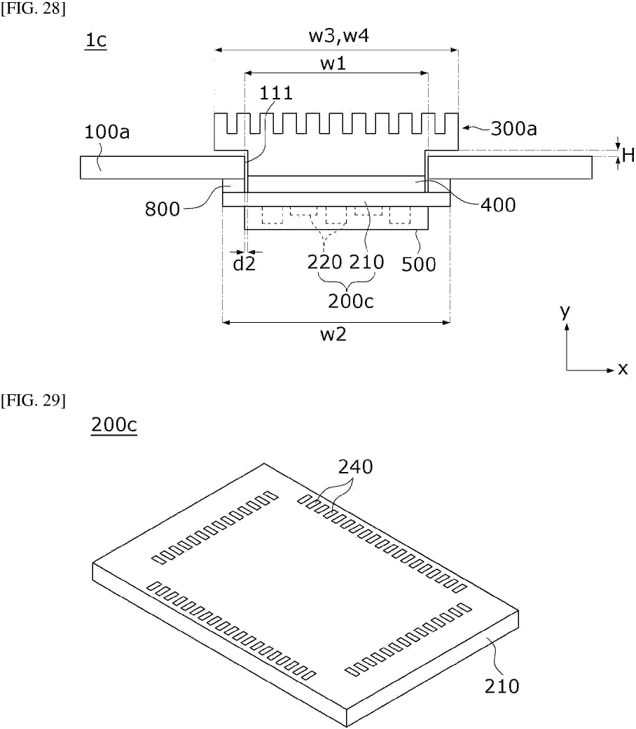

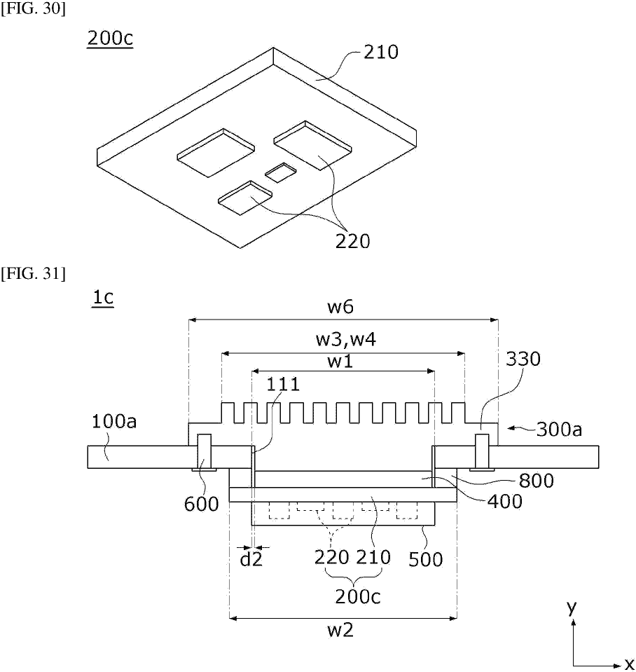

FIG. 27 is an exploded perspective view illustrating a communication module according to a fourth embodiment, FIG. 28 is a view illustrating the arrangement relationship of the communication module according to the fourth embodiment, FIG. 29 is a perspective view illustrating a communication unit disposed in the communication module according to the fourth embodiment, and FIG. 30 is a bottom perspective view illustrating the communication unit disposed in the communication module according to the fourth embodiment.

In a description of a communication module 1c according to the fourth embodiment with reference to FIGS. 27 and 30, since components the same as those of the communication module 1a according to second embodiment may be described with the same drawing numerals, detailed descriptions thereof will be omitted.

When comparing the communication module 1a according to second embodiment and the communication module 1c according to the fourth embodiment, the communication module 1c according to the fourth embodiment has a difference in that second terminals 240 formed on a second substrate 210 are included instead of the pads 230 of the communication module 1a according to second embodiment, and a first substrate 100 and the second substrate 210 are electrically connected by connectors 800 and 800a.

However, the communication module 1c according to the fourth embodiment may share a case in which an edge region of the second substrate 210 of a communication unit 200c is disposed to vertically overlap a periphery of the first hole 110 of the first substrate 100a with the communication module 1a according to second embodiment.

Referring to FIGS. 27 to 30, the communication module 1c according to the fourth embodiment may include the first substrate 100a having the first hole 110 formed herein, the communication unit 200c disposed at a lower side of the first substrate 100a, the heat sink 300a disposed at an upper side of the first substrate 100a, the thermally conductive member 400 disposed in the hole 110 to thermally connect the second substrate 210 of the communication unit 200a and the heat sink 300a, a cover 500 disposed to cover elements 220 of the communication unit 200a, and the connectors 800 and 800a which electrically connect the first substrate 100a and the second substrate 210 of the communication unit 200c.

Here, the communication unit 200c may include the second substrate 210, a plurality of elements 220 disposed on a lower surface, which is one surface of the second substrate 210, and a plurality of second terminals 240 disposed on an upper surface, which is the other surface of the second substrate 210. In this case, the second terminals 240 may be formed on the second substrate 210 to be exposed for an electrical connection with the connectors 800 and 800a.

Since the communication unit 200c is disposed at a the lower side of the first substrate 100a, the first metal pads 830 may be welded and bonded to the first terminals 120 of the first substrate 100 using spot welding using a laser, or may be electrically and physically bonded through a conductive adhesive such as a solder. Further, the second metal pads 840 may be welded and bonded to the second terminals 240 of the second substrate 210 using spot welding using a laser, or may be electrically and physically bonded through a conductive adhesive such as a solder.

FIG. 31 is a view illustrating a coupling relationship by fastening members of the communication module according to the fourth embodiment.

Referring to FIG. 31, the heat sink 300a may further include a first protrusion 330, which elongates the body 310 in the horizontal direction. Accordingly, the heat sink 300a may have a width W6 further extending in the horizontal direction from the width W3 in the horizontal direction of the body 310 due to the first protrusion 330.

Further, the first substrate 100a and the first protrusion 330 may be coupled by fastening members 600.

FIG. 32 is a view illustrating spacers of the communication module according to the fourth embodiment.

Referring to FIG. 32, the communication module 1c may further include spacers 700, which dispose the first substrate 100a and the first protrusion 330 so that the first substrate 100a and the first protrusion 330 are spaced apart from each other by a predetermined distance. Here, due to the spacers 700, predetermined spaces between the first substrate 100a and the first protrusion 330 may be secured, and heat dissipation paths through which heat is discharged may be secured.

Further, when the first substrate 100a and the first protrusion 330 are coupled by the fastening members 600, the spacers 700 may serve as buffer members.

Meanwhile, the above-described heat sinks 300 and 300a are exemplified as dissipating the heat of the communication module in an air-cooling manner, but the present invention is not necessarily limited thereto. For example, since an electronic element related to a network access device (NAD) has a greater heat generation amount compared to other elements, heat dissipation performance may be improved through a heat sink using a cooling medium method

That is, unlike the first or second heat sinks 300 and 300a, the communication module may improve heat dissipation performance using a third heat sink using a heat exchange medium (cooling medium). Here, the cooling medium may be a coolant or a refrigerant used in a vehicle. For example, the heat exchange medium may be a coolant used to lower engine heat or a refrigerant used in a vehicle air conditioner. In this case, when cooling water is used as a cooling medium of a third heat sink 300b, the third heat sink may be referred to as a water cooling-type heat sink.

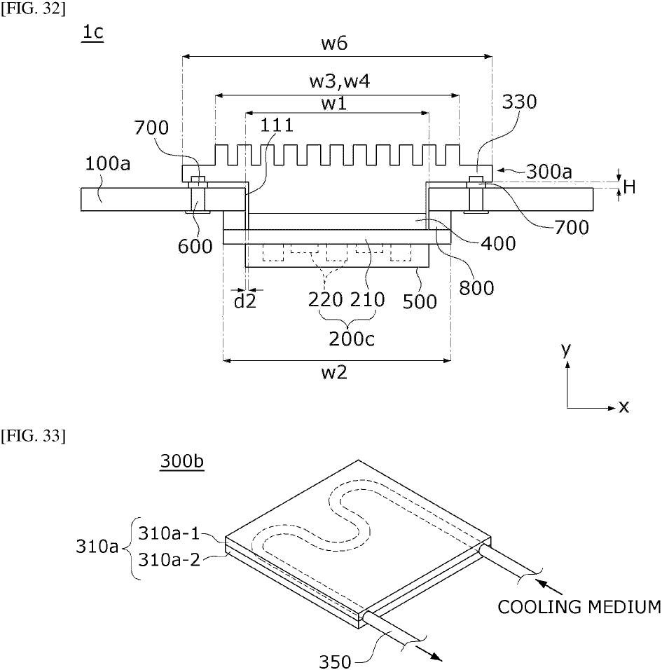

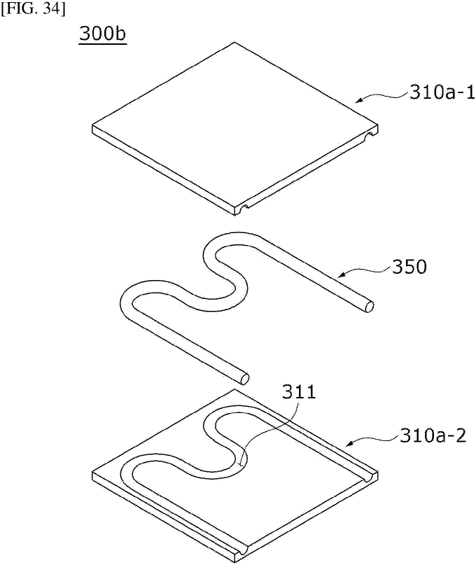

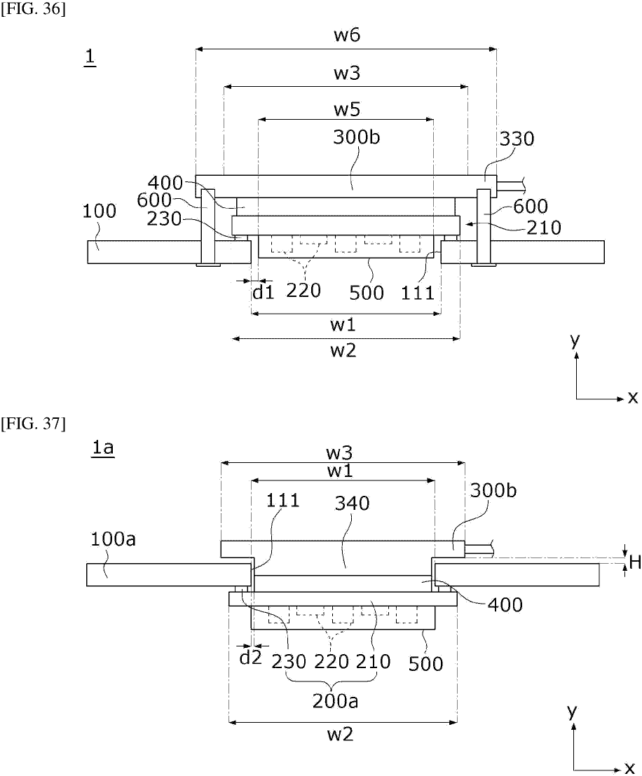

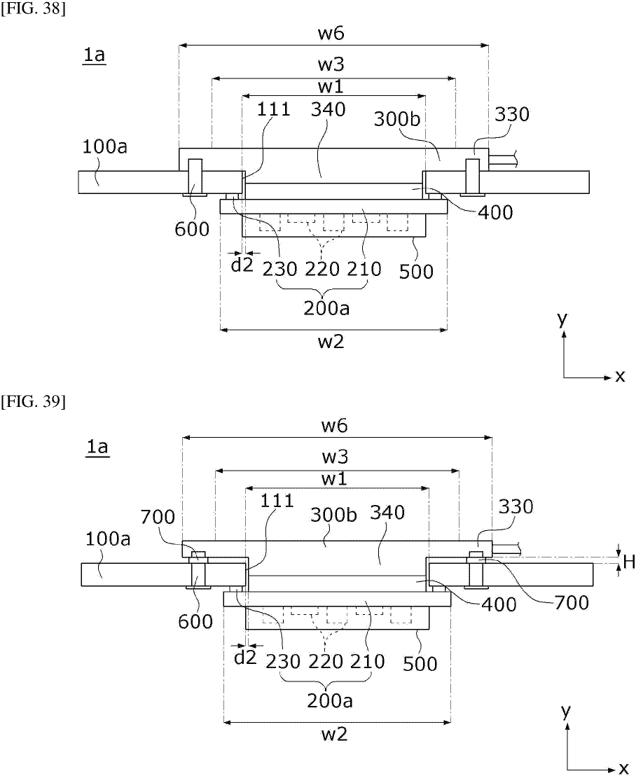

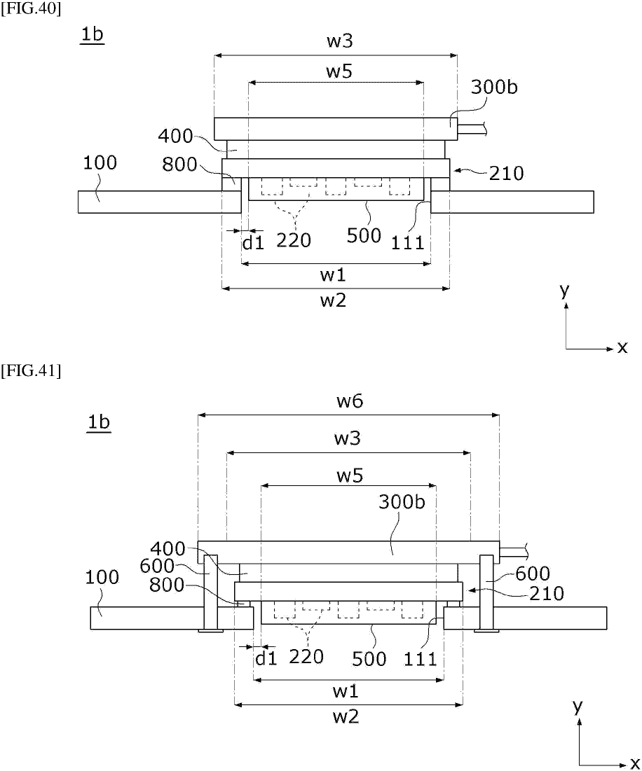

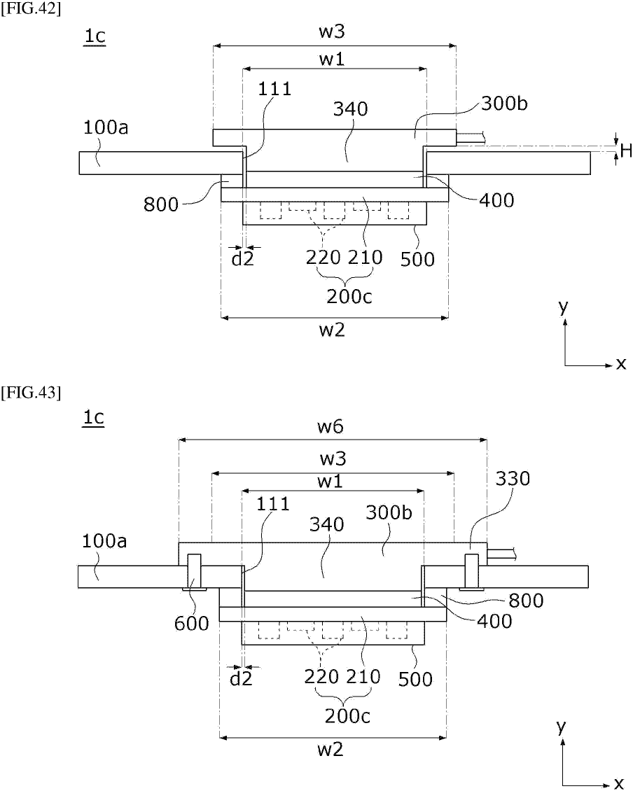

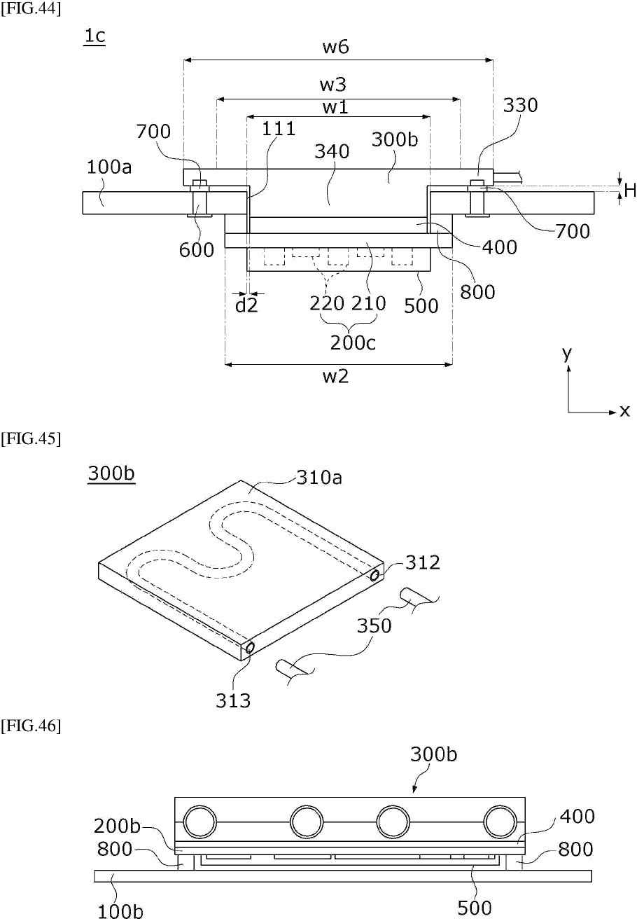

FIG. 33 is a perspective view illustrating a heat sink using a cooling medium according to an embodiment, FIG. 34 is an exploded perspective view illustrating the heat sink using the cooling medium according to the embodiment, FIG. 36 is a view illustrating a coupling relationship by the third heat sink and the fastening members applied to the communication module according to the first embodiment, FIG. 37 is a view illustrating the arrangement relationship of a third heat sink applied to the communication module according to the second embodiment, FIG. 38 is a view illustrating a coupling relationship by the third heat sink and the fastening members applied to the communication module according to the second embodiment, FIG. 39 is a view illustrating the arrangement relationship of the third heat sink and the spacers applied to the communication module according to the second embodiment, FIG. 40 is a view illustrating the arrangement relationship of a third heat sink applied to the communication module according to the third embodiment, FIG. 41 is a view illustrating a coupling relationship by the third heat sink and the fastening members applied to the communication module according to the third embodiment, FIG. 42 is a view illustrating the arrangement relationship of a third heat sink applied to the communication module according to the fourth embodiment, FIG. 43 is a view illustrating a coupling relationship by the third heat sink and the fastening members applied to the communication module according to the fourth embodiment, and FIG. 44 is a view illustrating the arrangement relationship of the third heat sink and the spacers applied to the communication module according to the fourth embodiment.

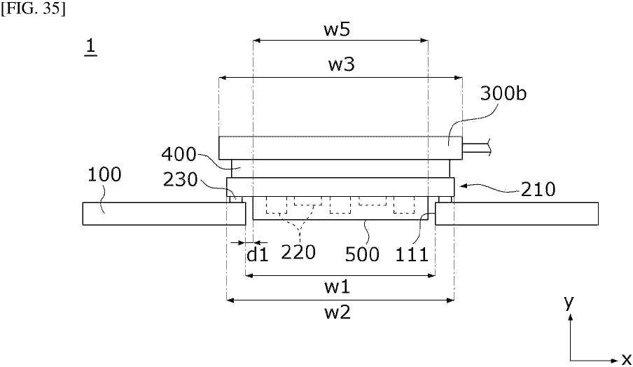

A heat sink 300b shown in FIGS. 33 and 34 may be disposed in the communication module instead of the first heat sink and the second heat sink. Here, the heat sink 300b shown in FIGS. 33 and 34 may be referred to as a third heat sink, and the third heat sink replace the body 310 of the first or second heat sink 300 or 300a. For example, as shown in FIGS. 35 to 43, the third heat sink 300b may be disposed in the above-described communication module to improve heat dissipation performance.

The heat sink 300b shown in FIGS. 33 and 34 may include a body 310a and a pipe 350 disposed in the body 310a. Here, the body 310a and the pipe 350 may be formed of a metal material having good thermal conductivity.

The body 310a may be formed in a flat plate shape, and may include an upper plate 310a-1 and a lower plate 310a-2 in consideration of the assemblability of the pipe 350. In this case, a groove 311 may be formed in each of the upper plate 310a-1 and the lower plate 310a-2 so that the pipe 350 may be disposed.

The pipe 350 is disposed to come into contact with the body 310a, and a cooling medium may flow through the pipe 350. Accordingly, the cooling medium may cool the body 310a by exchanging heat with heat transferred to the body 310a. In this case, a portion of the pipe 350 may be formed in a loop shape to improve heat exchange performance.

Meanwhile, in the heat sink 300b shown in FIGS. 33 and 34, only the body 310a without the pipe 350 may be provided. Accordingly, the groove 311 formed in each of the upper plate 310a-1 and the lower plate 310a-2 may be provided as a flow path through which a cooling medium may flow by coupling of the upper plate 310a-1 and the lower plate 310a-2.

Accordingly, one side of the flow path may be provided as an inlet through which the cooling medium is introduced, and the other side may be provided as an outlet through which the cooling medium introduced through the inlet is discharged. Further, a pipe may be connected to each of the inlet and the outlet to supply the cooling medium to the flow path. In this case, for a connection with the pipe, protrusions each having a semicircular cross-section may be further disposed at one side and the other side of the groove 311 of the upper plate 310a-1. Further, protrusions each having a semicircular cross-section may be further disposed at one side and the other side of the groove 311 of the lower plate 310a-2.

FIG. 45 is a view illustrating a modified example of the third heat sink.

As shown in FIG. 45, the body 310a of the third heat sink 300b may be formed as a single item. For example, the upper plate 310a-1 and the lower plate 310a-2 may be integrally formed using a die cast method or the like. However, the detachable body 310a shown in FIGS. 33 and 34 has an advantage of improving a degree of freedom in design, and the integrated body 310a shown in FIG. 45 has higher thermal conduction efficiency than the detachable body 310a.

In this case, a flow path may be formed in the integrated body 310a so that a cooling medium may flow therethrough, and an inlet 312 and an outlet 313 may be formed in the integrated body 310a so that the cooling medium may enter and exit the flow path. Further, the pipe 350 may be connected to the inlet 312 and the outlet 313 to supply the cooling medium to the flow path.

FIG. 46 is a view illustrating a communication module according to a fifth embodiment to which a third heat sink is applied.

Referring to FIG. 46, a communication module 1d according to the fifth embodiment may include a first substrate 100b, a communication unit 200b including a second substrate 210, and a plurality of elements 220 and a plurality of second terminals 240 disposed on one surface of the second substrate 210, a heat sink 300b disposed on the other surface of the second substrate 210, and connectors 800 which electrically connect the first substrate 100 and the second substrate 210. Further, the communication module 1d according to the fifth embodiment may further include a thermally conductive member 400 disposed between the heat sink 300b and the second substrate 210, and a cover 500 disposed to cover the elements 220 of the communication unit 200b.

The communication module 1d according to the fifth embodiment has a difference in that the first substrate 100b does not have the above-described first hole 110 compared to the communication module according to the third embodiment. Accordingly, an arrangement structure of the communication module 1d according to the fifth embodiment has a difference from the communication module according to the third embodiment.

The first substrate 100b may be formed in a plate shape, and there is a difference in that the first hole 110 is not formed unlike the first substrate 100 of the communication module according to the third embodiment.

The communication unit 200b may include the second substrate 210, the plurality of elements 220 disposed on the second substrate 210, and the plurality of second terminals 240 disposed on the second substrate 210.

The second terminals 240 may be formed on a lower surface of the second substrate 210. In this case, the second terminals 240 may be formed on the second substrate 210 to be exposed for an electrical connection with the connectors 800.

Referring to FIG. 46, the connectors 800 may be disposed between first terminals 120 formed on the first substrate 100b and the second terminals 240 formed on the second substrate 210. Accordingly, the connectors 800 may electrically connect the first substrate 100b and the communication unit 200b.

Accordingly, the communication module 1d may implement a stacked structure in which the first substrate 100b, the communication unit 200b, the thermally conductive member 400, and the heat sink 300b are stacked in the vertical direction. Accordingly, heat generated in the elements 220 may be transferred to the heat sink 300b through the thermally conductive member 400 and then cooled through heat exchange with the cooling medium.

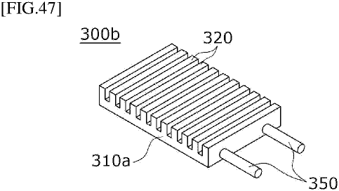

FIG. 47 is a view illustrating another modified example of the third heat sink.

Referring to FIG. 47, the third heat sink 300b may further include a plurality of heat dissipation fins 320 formed to protrude from the upper plate 310a-1. Here, the upper plate 310a-1 and the heat dissipation fins 320 may be integrally formed.

The heat dissipation fins 320 may be formed on all or a portion of an upper surface of the upper plate 310a-1. When the heat dissipation fins 320 are formed only on a portion of the upper plate 310a-1, the heat dissipation fins 320 may be formed to correspond to a partial region of the pipe 350. For example, a difference in temperatures of the cooling medium at inlet and outlet sides of the pipe 350 occurs due to heat exchange, and the temperature of the cooling medium at the outlet side is higher than the temperature at the inlet side. Accordingly, the heat dissipation fins 320 may be formed to correspond to the outlet side of the pipe 350 through which the cooling medium is discharged.

Accordingly, since the third heat sink 300b including the plurality of heat dissipation fins 320 is used, the communication module may further improve heat dissipation performance using air in addition to the cooling medium.

While the present invention has been described above with reference to exemplary embodiments, it may be understood by those skilled in the art that various modifications and changes of the present invention may be made within a range not departing from the spirit and scope of the present invention defined by the appended claims.

### Reference Numerals

1, 1a, 1b, 1c, 1d: communication module, 100, 100a: first substrate, 110: hole, 120: first terminal, 200, 200a, 200b, 200c: communication unit, 210: second substrate, 220: element, 230: pad, 240: second terminal, 300, 300a: heat sink, 310, 310a: body, 320: heat dissipation fin, 330: first protrusion, 340: second protrusion, 350: pipe, 400: thermally conductive member, 500: cover, 600: fastening member, 700: spacer, 800: connector

1. A communication module comprising:
a first substrate having a first hole formed herein;
a communication unit including a second substrate, and a plurality of elements disposed on one surface of the second substrate; and
a heat sink disposed on the other surface of the second substrate,
wherein an edge region of the second substrate is disposed to vertically overlap a periphery of the first hole of the first substrate,
wherein the communication unit further includes a plurality of pads disposed on the second substrate, and
wherein the pads are electrically connected terminals of the first substrate.

2-15. (canceled)

16. The communication module of claim 1, wherein the pads are disposed on the same surface as the surface of the second substrate, on which the elements are disposed, to be spaced apart from each other along the edge region.

17. The communication module of claim 16, further comprising a thermally conductive member disposed between the heat sink and the second substrate.

18. The communication module of claim 17, wherein:
the heat sink includes a body and a plurality of heat dissipation fins formed to protrude from one surface of the body;
the body includes a first protrusion protruding to further extend in a horizontal direction from a horizontal width (W4) of the plurality of heat dissipation fins; and
the first substrate and the first protrusion are coupled by fastening members.

19. The communication module of claim 1, wherein the pads are disposed on a surface different from the surface of the second substrate, on which the elements are disposed, to be spaced apart from each other along the edge region.

20. The communication module of claim 19, further comprising a thermally conductive member disposed between the heat sink and the second substrate,
wherein the thermally conductive member is disposed in the first hole.

21. The communication module of claim 20, wherein the thermally conductive member is disposed to be spaced apart from an inner surface of the first substrate forming the first hole by a predetermined distance.

22. The communication module of claim 21, wherein:
the heat sink includes a body, a plurality of heat dissipation fins formed to protrude from one surface of the body, and a second protrusion formed to protrude from the other surface of the body; and
the thermally conductive member is disposed between the second protrusion and the second substrate.

23. The communication module of claim 22, wherein the thermally conductive member and the second protrusion are disposed to be spaced apart from an inner surface of the first substrate forming the first hole by a predetermined distance.

24. The communication module of claim 23, wherein:
the body includes a first protrusion protruding to further extend in a horizontal direction from a horizontal width (W4) of the plurality of heat dissipation fins; and
the first substrate and the first protrusion are coupled by fastening members.

25. The communication module of claim 24, further comprising spacers disposed so that the first substrate and the first protrusion are spaced apart from each other by a predetermined distance.

26. The communication module of claim 1, wherein partial regions of the elements are disposed in the first hole.

27. The communication module of claim 1, wherein:
the heat sink includes a body, and a pipe disposed in the body; and
a cooling medium flows through the pipe.

28. The communication module of claim 1, further comprising a cover disposed to cover the elements,
wherein the cover is disposed in the first hole.

29. A communication module comprising:
a first substrate having a first hole formed herein;
a communication unit including a second substrate on which a plurality of elements are disposed on one surface thereof;
a heat sink disposed on the other surface of the second substrate; and
a connector disposed between the first substrate and the second substrate,
wherein the connector connects a first terminal of the first substrate and a second terminal of the second substrate.

30. The communication module of claim 29, wherein an edge region of the second substrate is disposed to vertically overlap a periphery of the first hole of the first substrate.

31. The communication module of claim 30, wherein the connector includes a third substrate having a second hole formed therein, a metal layer disposed on an inner surface of the second hole, a first metal pad disposed at one end of the metal layer, and a second metal pad disposed at the other end of the metal layer.

32. The communication module of claim 31, wherein:
the metal layer, the first metal pad, and the second metal pad are integrally formed;
the first metal pad comes into contact with the first terminal of the first substrate; and
the second metal pad comes into contact with the second terminal of the second substrate.

33. The communication module of claim 30, wherein:
the connector includes a third substrate having a groove formed therein, a metal layer disposed on an inner surface of the groove, a first metal pad disposed at one end of the metal layer, and a second metal pad disposed at the other end of the metal layer; and
the groove is concavely formed in a side surface of the third substrate in a horizontal direction.

34. The communication module of claim 33, wherein:
the metal layer, the first metal pad, and the second metal pad are integrally formed;
the first metal pad comes into contact with the first terminal; and
the second metal pad comes into contact with the second terminal.
